(19) United States
(12) Patent Application Publication
(10) Pub. No.: US 2014/0127852 A1
(43) Pub. Date: May 8, 2014

(54) LOW VACUUM FABRICATION OF MICROCRYSTALLINE SOLAR CELLS

(71) Applicant: INTERNATIONAL BUSINESS MACHINES CORPORATION, Armonk, NY (US)

(72) Inventors: Joel P. de Souza, Putnam Valley, NY (US); Marinus J. Hopstaken, Carmel, NY (US); Jeehwan Kim, White Plains, NY (US); Devendra K. Sadana, Pleasantville, NY (US)

(73) Assignee: International Business Machines Corporation, Armonk, NY (US)

(21) Appl. No.: 13/671,104

(22) Filed: Nov. 7, 2012

(51) Int. Cl. H01L 31/18

(52) U.S. Cl. CPC H01L 31/1824
USPC 438/97

(57) ABSTRACT

A device and method for forming a photovoltaic device include forming a photovoltaic stack of layers on a transparent substrate wherein at least one layer of the photovoltaic stack of layers includes a microcrystalline layer. The microcrystalline layer is formed by purging a vacuum chamber with a gettering gas to remove contaminant species from the chamber prior to forming the microcrystalline layer. The microcrystalline layer is deposited at a vacuum base pressure of greater than about 10⁻² Torr.

### BACKGROUND

1. Technical Field

The present invention relates to photovoltaic devices and fabrication thereof, and more particularly to low vacuum fabrication of photovoltaic devices formed.

2. Description of the Related Art

Solar energy becomes a viable energy source when fabrication and operating costs are reduced enough to make it a reasonable substitute for other energy systems. Amorphous silicon solar cells have made significant progress in reducing production costs of solar panels. However, in order for solar cells to be more affordable, additional reductions in costs and greater efficiencies are needed.

Like semiconductor processing, photovoltaic devices are typically fabricated in vacuum chambers under elevated temperature conditions. Creating and maintaining low pressure and elevated temperature environments is expensive. It would be desirable to reduce the number of processes that need to be performed in such environments to preserve thermal budget, maintain or improve efficiency and reduce costs of processing.

### SUMMARY

A device and method for forming a photovoltaic device include forming a photovoltaic stack of layers on a substrate wherein at least one layer of the photovoltaic stack of layers includes a microcrystalline layer; and forming the microcrystalline layer. The microcrystalline layer is formed by: purging a vacuum chamber with a gettering gas to remove contaminant species from the chamber prior to forming the microcrystalline layer; and depositing the microcrystalline layer at a vacuum base pressure of greater than about 5×10⁻⁵ Torr.

Another method for forming a photovoltaic device includes forming an electrode on a substrate; forming an amorphous based silicon pin stack over the electrode; forming a microcrystalline based silicon pin stack over the amorphous based silicon stack to form a multi-junction device, wherein at least one layer of the microcrystalline based silicon stack includes a microcrystalline layer. The microcrystalline layer is formed by: purging a vacuum chamber with a gettering gas to remove contaminant species from the chamber prior to form the microcrystalline layer; and depositing the microcrystalline layer at a vacuum base pressure of greater than about 10⁻² Torr.

Yet another method for forming a photovoltaic device includes forming a photovoltaic stack of layers on a substrate wherein at least one layer of the photovoltaic stack of layers includes a microcrystalline layer; and forming the microcrystalline layer. The microcrystalline layer is formed by: purging a vacuum chamber with a gettering gas to remove contaminant species from the chamber prior to forming the microcrystalline layer; and depositing the microcrystalline layer at a vacuum pressure.

A photovoltaic device prepared by a process is provided. The process includes forming a photovoltaic stack of layers on a substrate wherein at least one layer of the photovoltaic stack of layers includes a microcrystalline layer; and forming the microcrystalline layer by: purging a vacuum chamber with a gettering gas to remove contaminant species from the chamber prior to forming the microcrystalline layer; and depositing the microcrystalline layer at a low vacuum base pressure of greater than about 10⁻² Torr while maintaining microcrystalline quality comparable to the microcrystalline quality obtained by use of a ultra-high vacuum base pressure for deposition.

Another photovoltaic device is prepared by a process including forming an electrode on a substrate; forming an amorphous based silicon stack over the electrode; forming a microcrystalline based silicon stack over the amorphous based silicon stack to form a multi-junction device, wherein at least one layer of the microcrystalline based silicon stack includes a microcrystalline layer; and forming the microcrystalline layer by: purging the vacuum chamber with a gettering gas to remove contaminant species from the chamber prior to forming the microcrystalline layer; and depositing the microcrystalline layer with a microcrystalline quality comparable to the microcrystalline quality obtainable by use of an ultra-high vacuum base pressure prior to deposition.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a photovoltaic device having one or more microcrystalline layers in accordance with the present principles;

FIG. 2 is a plot of current density (mA/cm²) versus voltage (V) for a photovoltaic device having a microcrystalline intrinsic layer formed at a pressure of 5×10⁻⁵ Torr, the device showing shunting behavior due to the presence of background gases of a photovoltaic device;

FIG. 3A is a plot of concentration (atoms/cm³) versus depth (Angstroms) for a photovoltaic device having a microcrystalline intrinsic layer formed at a low base vacuum pressure (greater than of 5×10⁻⁵ Torr) with SiH₄ flushing prior top formation of the intrinsic layer, the device showing reduced background gas (N) by an order of magnitude in accordance with the present principles;

FIG. 3B is a plot of concentration (atoms/cm³) versus depth (Angstroms) for a photovoltaic device having a microcrystalline intrinsic layer formed at a low base pressure (greater than of 5×10⁻⁵ Torr) with SiH₄ flushing prior top formation of the intrinsic layer, the device showing reduced background gas (O) by an order of magnitude in accordance with the present principles;

FIG. 3C is a plot of concentration (atoms/cm³) versus depth (Angstroms) for a photovoltaic device having a microcrystalline intrinsic layer formed at a low base pressure (greater than of 5×10⁵ Torr) with SiH₄ flushing prior top formation of the intrinsic layer, the device showing reduced background gas (O) by an order of magnitude in accordance with the present principles;

FIG. 4 is a plot of current density (mA/cm²) versus voltage (V) for one photovoltaic device having a microcrystalline intrinsic layer formed without a SiH₄ purge and one photovoltaic device having a microcrystalline intrinsic layer formed after a SiH₄ purge in accordance with the present principles;

FIG. 5 shows plots of current density (J) (mA/cm²) versus voltage (V) for photovoltaic devices having a microcrystalline intrinsic layer formed at different vacuum base pressures including 1) no SiH₄ purge and base pressure at 5×10⁻⁵ Torr (FF=28), 2) with SiH₄ purge and base pressure 10⁻¹ Torr (FF=60%) and 3) with SiH₄ purge and base pressure of 5×10⁻⁵ Torr (FF=65%);

FIG. 6 is a schematic diagram illustratively showing a vacuum chamber purge in accordance with one embodiment; and

FIG. 7 is a block/flow diagram showing methods for forming a photovoltaic device in accordance with illustrative embodiments.

### DETAILED DESCRIPTION OF PREFERRED EMBODIMENTS

In accordance with the present principles, methods and devices are disclosed which are fabricated with microcrystalline materials in low vacuum (e.g., higher pressure) environments. In many instances, reduction of costs (e.g., dollars per Watt) for silicon-based solar cells can be achieved by going from an amorphous single junction cell (e.g., a-Si:H) to a tandem or multi junction cell since a tandem cell provides greater efficiency with little additional cost.

In one embodiment, a microcrystalline silicon/amorphous silicon (e.g., μc-Si:H/a-Si:H) tandem cell can be made with comparable cost to that of a single junction (e.g., a-Si:H) cell. However, microcrystalline material needs to be processed in a system with very low base pressure (e.g., 10⁻⁶ Torr) to achieve a structure for proper functioning of the tandem cell. In accordance with the present principles, methods and devices are provided that employ a low vacuum base pressure (e.g., 5×10⁻⁵ to 10⁻¹ Torr) but still maintain low cost and maintain or improve efficiency of solar cells. To achieve a low base vacuum pressure a purge is performed prior to the formation of the microcrystalline layer. In one embodiment, the purge may be employed with any base vacuum pressure to improve the quality of the microcrystalline phase.

In accordance with the present principles, a single junction cell may be manufactured with microcrystalline Si (e.g., instead of a-Si) at less cost. In addition, the present principles may be employed to form a tandem cell without needing a high vacuum chamber system.

The present principles employ a purge gas that reacts with oxygen, nitrogen, carbon and other contaminates in a system to enable microcrystalline growth with reduced impurities. This assists in increasing efficiency in performance and cost. In one particularly useful embodiment, a reactive purge gas (e.g., SiH₄) is employed in a deposition chamber to reduce contaminants, in particular oxygen, carbon and nitrogen prior to microcrystalline formation. By employing a purge gas just before the microcrystalline formation, the purity obtained for this material in a system with low vacuum is comparable to that obtained after high vacuum pumping.

It is to be understood that the present invention will be described in terms of a given illustrative architecture having substrates and photovoltaic stacks; however, other architectures, structures, substrates, materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for a photovoltaic device may be created for integrated circuit integration, used alone as a solar cell or may be combined with components on a printed circuit board. The circuit/board may be embodied in a graphical computer programming language, and stored in a computer storage medium (such as a disk, tape, physical hard drive, or virtual hard drive such as in a storage access network). If the designer does not fabricate chips or the photolithographic masks used to fabricate chips or photovoltaic devices, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of photovoltaic devices and/or integrated circuit chips with photovoltaic devices. The resulting devices/chips can be distributed by the fabricator in raw wafer form (that is, as a single wafer that has multiple unpackaged devices/chips), as a bare die, or in a packaged form. In the latter case, the device/chip is mounted in a single chip package (such as a plastic carrier, with leads that are affixed to a motherboard or other higher level carrier) or in a multichip package (such as a ceramic carrier that has either or both surface interconnections or buried interconnections). In any case, the devices/chips are then integrated with other chips, discrete circuit elements, and/or other signal processing devices as part of either (a) an intermediate product, such as a motherboard, or (b) an end product. The end product can be any product that includes integrated circuit chips, ranging from toys, energy collectors, solar devices and other applications including computer products or devices having a display, a keyboard or other input device, and a central processor. The photovoltaic devices described herein are particularly useful for solar cells or panels employed to provide power to electronic devices, homes, buildings, vehicles, etc.

It should also be understood that material compounds will be described in terms of listed elements, e.g., SiC or SiGe. These compounds may include different proportions of the elements within the compound, e.g., SiGe includes SiₓGe₁₋ₓ where x is less than or equal to 1, etc. In addition, other elements or dopants may be included in the compound, such as, e.g., SiGe:H, and still function in accordance with the present principles.

The present embodiments may be part of a photovoltaic device or circuit, and the circuits as described herein may be part of a design for an integrated circuit chip, a solar cell, a light sensitive device, etc. The photovoltaic device may be a large scale device on the order of feet or meters in length and/or width, or may be a small scale device for use in calculators, solar powered lights, etc.

It is also to be understood that the present invention will be described in terms of a particular tandem (multi-junction) structure; however, other architectures, structures, substrate materials and process features and steps may be varied within the scope of the present invention. The tandem structure includes cells, which will be described in terms of a particular material. Each cell includes a p-doped layer, an n-doped layer and perhaps an undoped intrinsic layer.

Reference in the specification to “one embodiment” or “an embodiment” of the present principles, as well as other variations thereof, means that a particular feature, structure, characteristic, etc. described in connection with the embodiment is included in at least one embodiment of the present principles. Thus, the appearance of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

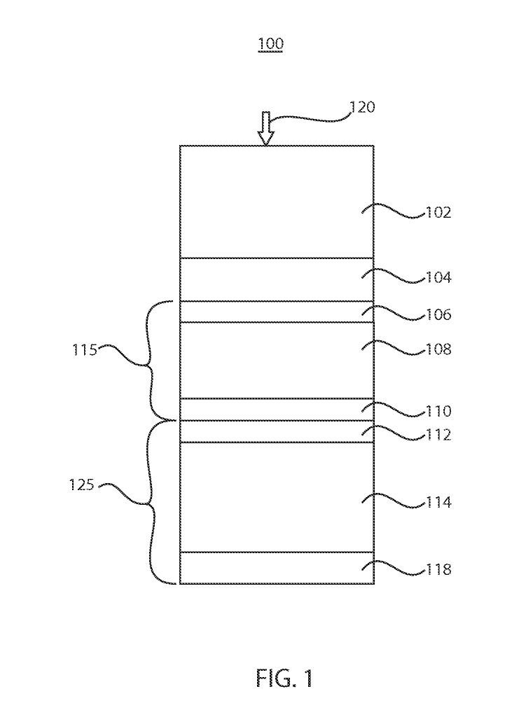

Referring now to the drawings in which like numerals represent the same or similar elements and initially to FIG. 1, an illustrative photovoltaic structure 100 is depicted in accordance with one embodiment. The photovoltaic structure 100 may be employed in solar cells, light sensors or other photovoltaic applications. Structure 100 includes a substrate 102 that permits a high transmittance of light. The substrate 102 may include a transparent material, such as glass, a polymer, etc. or combinations thereof or an opaque material silicon, metal, etc.

A first electrode 104 may include a transparent conductive material. Electrode 104 may include a doped layer, e.g., an N-type dopant layer or a P-type dopant layer. Electrode 104 may include a transparent conductive oxide (TCO), such as, e.g., a fluorine-doped tin oxide (SnO₂:F, or “FTO”), doped zinc oxide (e.g., ZnO:Al), indium tin oxide (ITO) or other suitable materials. For the present example, a doped zinc oxide is illustratively employed for electrode 104. The TCO 104 permits light to pass through to an active light-absorbing material beneath and allows conduction to transport photo-generated charge carriers away from that light-absorbing material.

The light-absorbing material includes a doped layer 106 (e.g., a doped amorphous silicon (a-Si) or microcrystalline silicon (μc-Si) layer, and in particular a P-type doped layer). In this illustrative structure 100, layer 106 is formed on electrode 104. An intrinsic layer 108 of compatible material is formed on layer 106. Intrinsic layer 108 may be undoped and may include an amorphous silicon material. The intrinsic layer 108 may include a thickness of between about 100-300 nm, although other thicknesses are contemplated.

The intrinsic layer 108 is preferably a thin film hydrogenated amorphous silicon (a-Si:H) or a hydrogenated amorphous silicon carbide (a-SiC:H) which may be deposited by a chemical vapor deposition (CVD) process, or a plasma-enhanced CVD (PECVD)) from silane gas and hydrogen gas.

In one embodiment, a second doped layer 110 (e.g., an N-type layer) is formed on the intrinsic layer 108 as an N-type tunnel junction. Intrinsic layer 108 may include an amorphous hydrogenated silicon (a-Si:H), and layer 110 preferably includes an N-type hydrogenated microcrystalline (μc-Si:H). The layer 110 may include an ultra-thin thickness, e.g., between about 0.1 nm to about 20 nm and more preferably less than about 5 nm. To promote conductivity of the tunnel junction 110, more doping may be provided in this region.

To increase the performance of the device 100, it is desirable that any radiation that passes through a top cell 115 is absorbed in a lower cell(s) 125. This is achieved by providing energy gap splitting (E_{g} splitting). For example, the top cell 115 has higher band gap materials and receives light 120 first. The light spectra that are not absorbed at the top cell 115 enter the cell 125. A larger band gap difference between two different junctions is better to prevent the light spectra from being shared between the junctions. This is to maximize photocurrent. Energy gap splitting permits the absorption of radiation with different energies between the cells. Since the band gap of the top cell 115 is maintained at a higher level, the lower level cell(s) 125 is/are designed to have a lower band gap. In this way, the lower cells have a higher probability of absorbing transmitted radiation, and the entire multi junction cell becomes more efficient since there are fewer photon energy levels shared between the layered cells. This results in an increased probability of absorbing light passing through to the bottom cell 125 hence increasing the current in the lower cells 125 and increasing short circuit current, J_{SC}.

It should be understood that the cells 115 and 125 include pin stacks (P-type layer, Intrinsic layer and N-type layer); however, NIP stacks may be employed as well. E.g., the substrate 102 may include an opaque material and instead of PIN stacks, the NIP stacks may be employed (with light being received on a side opposite the opaque substrate). Other configurations are contemplated as well. Also, while two cells 115 and 125 are depicted, additional cells may be added, as needed.

To increase efficiency, it is preferable that a greater difference between band gaps exists between the top cell 115 (higher band gap), and the bottom cell 125 (lower band gap) by keeping an absolute high level of band gap energy (E_{g}) for all cells to maintain high open circuit voltage, Voc.

The bottom cell 125 in the present embodiment includes a doped layer 112 (e.g., P-type), which is formed on the N-type layer 110 as a P-type tunnel junction. The layer 112 preferably includes a P-type hydrogenated microcrystalline silicon (μc-Si:H). The layer 112 may be grown on the layer 110 or may be grown in a continuous process with layer 110, switching the dopant types during the deposition process to form both layers 110 and 112. The layer 112 may include an ultra-thin thickness, e.g., of between about 0.1 nm to about 20 nm and more preferably less than about 5 nm. An intrinsic layer 114 of compatible material (e.g., microcrystalline Si) is formed on layer 112.

With the microcrystalline structure provided for tunnel junction layers 110 and 112, the active doping concentration can effectively be increased by one or two orders of magnitude compared with a doping capacity of an amorphous phase, thus increasing conductivity and overall cell efficiency. Intrinsic layer 114 may be undoped. The intrinsic layer 114 may include a thickness of about 150 nm, although other thicknesses are contemplated.

In this embodiment, an N-type layer 118 is formed on the intrinsic layer 114. Layer 118 preferably includes an N-type amorphous or microcrystalline silicon. One or more of layers 112, 114 and 118 may include a hydrogenated microcrystalline silicon material (μc-Si:H), a hydrogenated amorphous silicon germanium (e.g., a-SiGe:H) material, a microcrystalline silicon germanium (μc-SiGe:H) or other suitable material (e.g., microcrystalline germanium). The layer 118 may include an ultra-thin thickness, e.g., less than about 20 nm and more preferably less than about 5 nm. Additional cells and/or layers (e.g., reflectors, etc.) may be formed after cell 125 is completed. In particularly useful embodiments, top cell 115 may include layers comprised of a-Si:H and/or a-SiC:H and the bottom cell 125 may include layers comprised of a-SiGe:H and/or μc-Si:H. It should be noted that the tandem cells may include the same materials or other materials from those presented. Additional layers may be added to layer 118 including but not limited to additional pin stacks, back reflectors, transparent electrodes, etc.

As illustratively noted above one or more layers of the tandem cell structure 100 may include microcrystalline materials, e.g., μc-Si:H, μc-SiGe:H, μc-Ge. To reduce cost, the normally required high to ultra-high vacuum needed to form microcrystalline materials is avoided in accordance with the present principles. One of the factors affecting quality of microcrystalline materials and their formation is the presence of oxygen, carbon and nitrogen during the formation of the microcrystalline layer. For example, any oxygen (or nitrogen) present in a processing chamber becomes doped into the microcrystalline materials and acts as an N-type dopant in the microcrystalline semiconductor material. This has a particularly negative impact on P-type and intrinsic layers formed in the structure 100. To avoid the presence of oxygen and other contaminants, during the formation of microcrystalline materials, a high or ultra-high vacuum (UHV) (e.g., 10⁻⁶Torr or less) is required. However, to pull and maintain a vacuum at this level is difficult, requiring expensive vacuum pumps and requiring a longer set up time to achieve the appropriate vacuum level. Such low vacuum pressures are needed for a solar cell with microcrystalline Si to be operational.

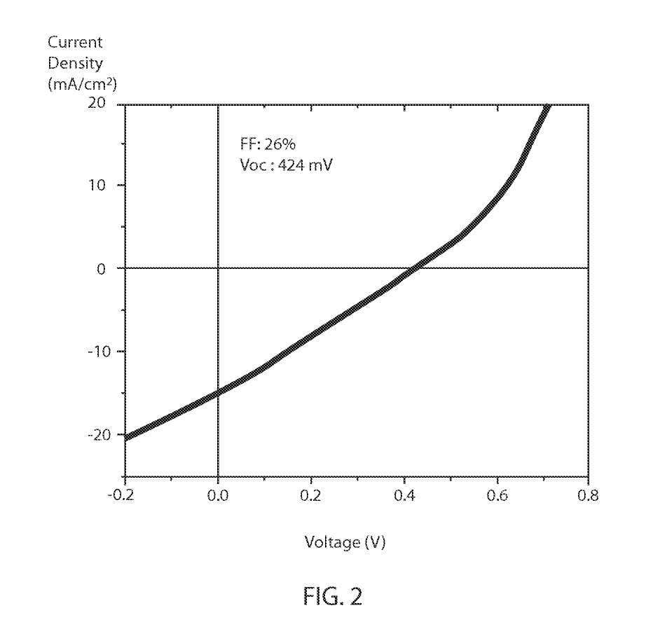

Referring to FIG. 2, a graph of current density (mA/cm²) versus voltage (V) is shown for a microcrystalline Si:H intrinsic layer formed at 5×10⁻⁵ Torr for a solar cell. The device formed is shunted due to high background gas present during formation of the intrinsic layer, in particular, the presence of oxygen and nitrogen, which are N-type dopants. The processing gas for forming the intrinsic layer includes H₂ and SiH₄ in a ratio of [H₂]/[SiH₄] of 120 in this case. The background gas included O (e.g., O₂, H₂O, CO₂, etc.), N (e.g., N₂), C (e.g., hydrocarbons, CO₂, etc.) and other gases. The shunted devices had a fill factor (FF) of about 26% and an open circuit voltage, Voc=424 mV. While these gases can be further reduced, it comes at the expense of higher vacuum pressure (e.g., pressure around 10⁻⁶ Torr or below).

In accordance with the present principles, UHV is avoided by employing a gas flushing process. The gas flushing process is preferably employed prior to forming a microcrystalline layer. The flushing gas not only flushes a chamber, but is selected to react with or getter contaminant gases, such as O, N, C, etc.

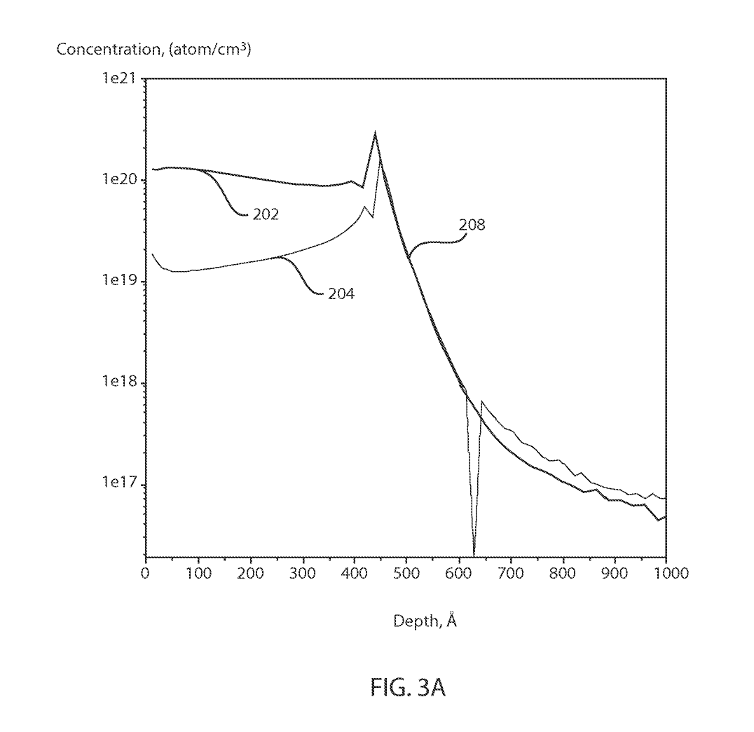

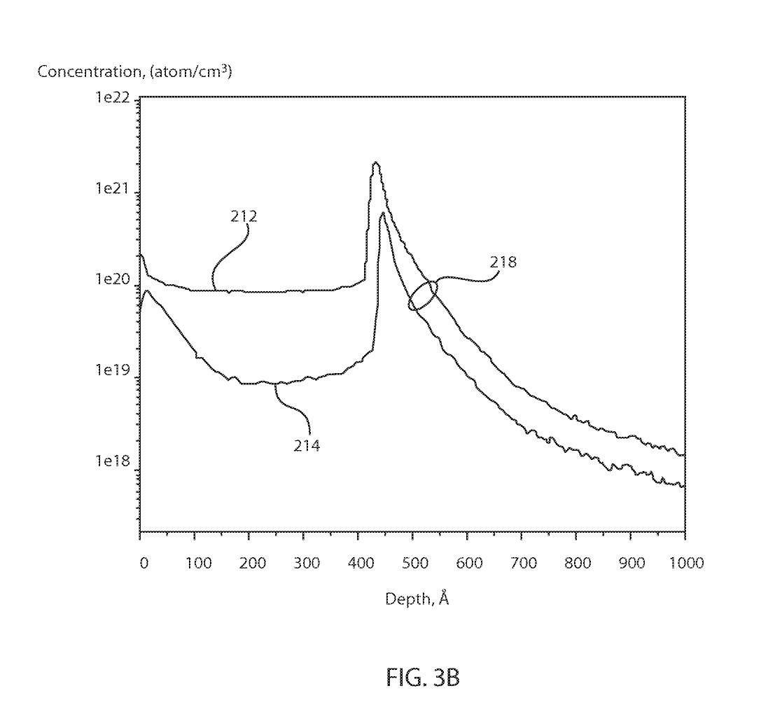

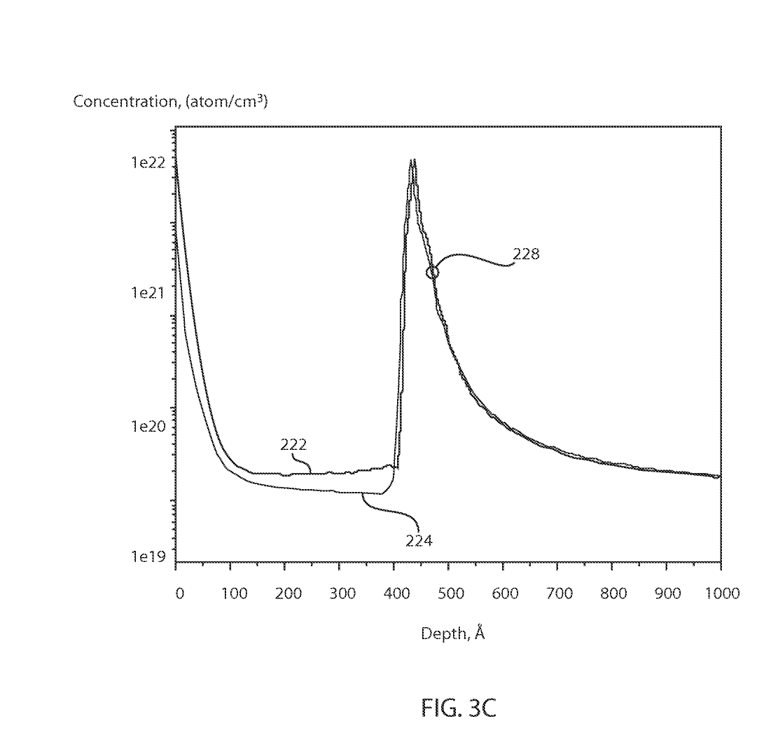

Referring to FIG. 3A, a graph shows effects of flushing a chamber with SiH₄ to getter background gas in accordance with one embodiment. The graph shows profiles of nitrogen in an intrinsic layer. A horizontal axis shows depth of the intrinsic layer in Angstroms, a left side vertical axis shows concentration in atoms/cm³. A control plot 202 shows a nitrogen profile for a hydrogenated microcrystalline silicon (μc-Si:H) intrinsic layer formed using a base pressure of 5×10⁻⁵ Torr (high vacuum). Plot 204 shows a profile for a hydrogenated microcrystalline silicon (μc-Si:H) intrinsic layer formed using a flushing gas (SiH₄) to getter background gas using the same base pressure. As an example, by flushing SiH₄ prior to microcrystalline formation, the nitrogen contamination in the layer is reduced by more than one order of magnitude from the control plot 202. Other flushing gases may be employed instead of or in addition to SiH₄ to getter and remove contaminates. The quick trail off region 208 begins at the end of the intrinsic layer.

Referring to FIG. 3B, another graph shows effects of flushing a chamber with SiH₄ to getter background gas. The graph shows profiles of carbon in the intrinsic layer. A horizontal axis shows depth of the intrinsic layer in Angstroms, a left side vertical axis shows concentration in atoms/cm³. A control plot 212 shows a carbon profile for a hydrogenated microcrystalline silicon (μc-Si:H) intrinsic layer formed using a base pressure of 5×10⁻⁵ Torr (high vacuum). Plot 214 shows a profile for a hydrogenated microcrystalline silicon (μc-Si:H) intrinsic layer formed using a flushing gas (SiH₄) to getter background gas at a same base pressure. As an example, by flushing SiH₄ prior to microcrystalline formation, the carbon contamination in the layer is reduced by more than one order of magnitude from the control plot 212. Other flushing gases may be employed instead of or in addition to SiH₄ to getter and remove contaminates. The quick trail off region 218 begins at the end of the intrinsic layer.

Referring to FIG. 3C, another graph shows effects of flushing a chamber with SiH₄ to getter background gas. The graph shows profiles of oxygen in the intrinsic layer. A horizontal axis shows depth of the intrinsic layer in Angstroms, a left side vertical axis shows concentration in atoms/cm³. A control plot 222 shows an oxygen profile for a hydrogenated microcrystalline silicon (μc-Si:H) intrinsic layer formed using a base pressure of 5×10⁻⁵ Torr (high vacuum). Plot 224 shows a profile for a hydrogenated microcrystalline silicon (μc-Si:H) intrinsic layer formed using a flushing gas (SiH₄) to getter background gas at a same base pressure. As an example, by flushing SiH₄ prior to microcrystalline formation, the oxygen contamination in the layer is significantly reduced from the control plot 222. Other flushing gases may be employed instead of or in addition to SiH₄ to getter and remove contaminates. The quick trail off region 228 begins at the end of the intrinsic layer.

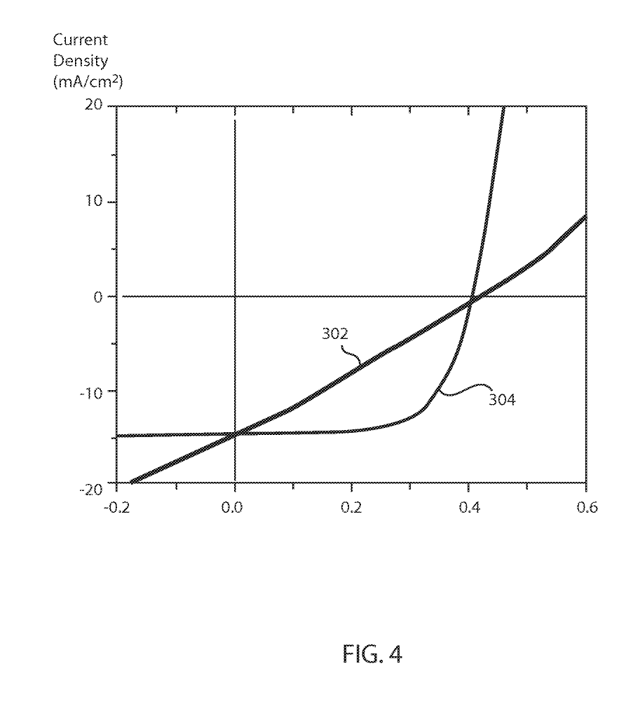

Referring to FIG. 4, a graph of current density (mA/cm²) versus voltage (V) is shown depicting a plot 302 similar to FIG. 2 for a microcrystalline Si:H intrinsic layer formed at 5×10⁻⁵ Torr. Plot 302 is formed without a SiH₄ purge. As described, the plot 302 corresponds with a solar cell with a fill factor of 28%. FIG. 4 also includes a plot 304 for a microcrystalline Si:H intrinsic layer formed with a SiH₄ purge at 5×10⁻⁵ Ton in accordance with the present principles. The plot 304 corresponds with a solar cell with a fill factor of 65%.

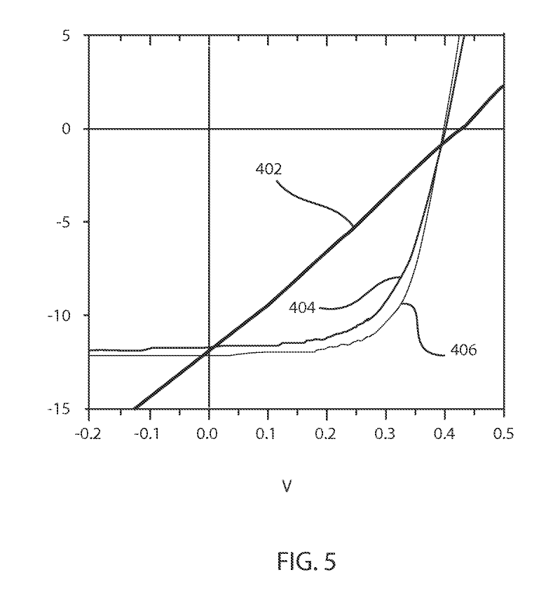

Referring to FIG. 5, plots of current density (J) (mA/cm²) versus voltage (V) are shown for photovoltaic devices having a microcrystalline intrinsic layer formed at different vacuum base pressures. Plot 402 shows a response for a device having an intrinsic layer formed without a SiH₄ purge and with a base pressure of 5×10⁻⁵ Ton (FF=28%). Plot 404 shows a response for a device having an intrinsic layer formed with a SiH₄ purge and with a base pressure of 10⁻¹ Torr (FF=60%). Plot 406 shows a response for a device having an intrinsic layer formed with a SiH₄ purge and with a base pressure of 5×10⁻⁵ Torr (FF=65%). It can be seen that the purge step provides a microcrystalline layer of comparable quality (FF=60% versus FF=65%) even with base vacuum pressures as high as 10⁻¹ Torr.

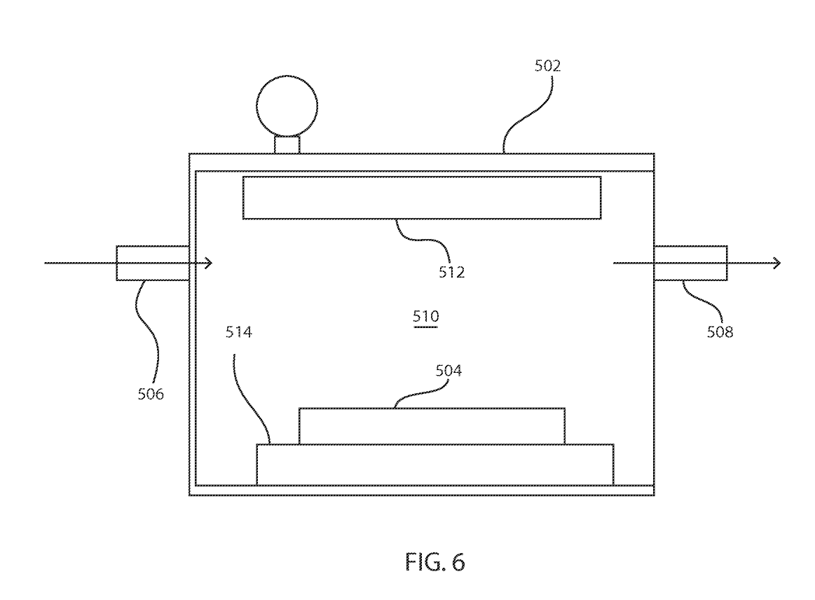

Referring to FIG. 6, a vacuum chamber 502 includes a photovoltaic substrate/device 504 prepared for processing. Prior to the formation of a microcrystalline layer on the device 504, the chamber 502 is purged using a gettering gas present in an interior volume 510 of the chamber 502. The gettering gas in volume 510 is pumped into the chamber 502 through an inlet 506 and removed through an outlet 508. It should be understood that the inlet 506 and outlet 508 may include different configurations, and are shown here illustratively. The gettering gas may include silane (SiH₄) and its related compounds (e.g., disilane, trisilane, tetrasilane, etc), silane diluted in inert gas (e.g., He, Ar, etc.) and/or other reactive elements, e.g., sublimated titanium atoms, aluminum atoms, magnesium atoms, etc. Other gettering gases may include silicon fluoride (tetrafluorosilane), diborane and related compounds (e.g., dihydrotetraborane, pentaborane, hexaborane, etc.), phosphorous fluoride, phosphine, organosilanes, germanium fluoride, etc. Silane is particularly useful in improving the quality of microcrystalline silicon layers or materials. Silane is reactive with contaminant species, e.g., O, N, C, etc., and, by flushing the chamber, the reactants are removed from the chamber 502. The purge is preferably conducted at a temperature, e.g., between about room temperature to about 300 degrees C. although higher temperatures may be employed. The getter or purge gas may flow through the chamber 502 for between about 20 seconds to one hour, although between about 1 minute to about 10 minutes, is preferred. The purge may be conducted at atmospheric pressures although pulling a vacuum pressure can assist in removing contaminates.

After purging the chamber 502, the microcrystalline layer is deposited by plasma enhanced chemical vapor deposition PECVD or other method from a mixture of silane and hydrogen gases at reduced pressure (e.g., 1-10 Torr).

The low vacuum base pressure provides ease of manufacturing, reduces equipment requirements, reduces process time (less time to pull a vacuum), etc. In one embodiment, the purge process may also be employed with the ultra high vacuum process to provide even higher quality microcrystalline structures. In either case, the microcrystalline quality is at least comparable to the microcrystalline quality obtained by using the ultra high vacuum pressure alone. The microcrystalline layer may include hydrogenated microcrystalline silicon, hydrogenated microcrystalline germanium, hydrogenated microcrystalline silicon germanium, etc. The deposition process may include chemical vapor deposition, (CVD), PECVD, or any other process to form the microcrystalline layer. Electrodes 512 and 514 are illustratively shown for use in plasma deposition processes, etc.

The microcrystalline layer formed in accordance with the present principles will be formed of higher quality using the purge gas than without employing the purge gas (see FIGS. 4, 5). In this way, an ultra high vacuum or a low vacuum base pressure may be employed to achieve a microcrystalline silicon layer capable of operation in a photovoltaic device. In one embodiment, the microcrystalline layer formed in accordance with the present principles includes a combined oxygen, nitrogen and carbon concentration of less than 5×10¹⁹ cm⁻³.

Note that the purge before deposition may be implemented one or more times during the formation of a photovoltaic stack. In one embodiment, the purge is performed before each microcrystalline layer is formed. The microcrystalline layer may be included in a single junction device or in a multi-junction device.

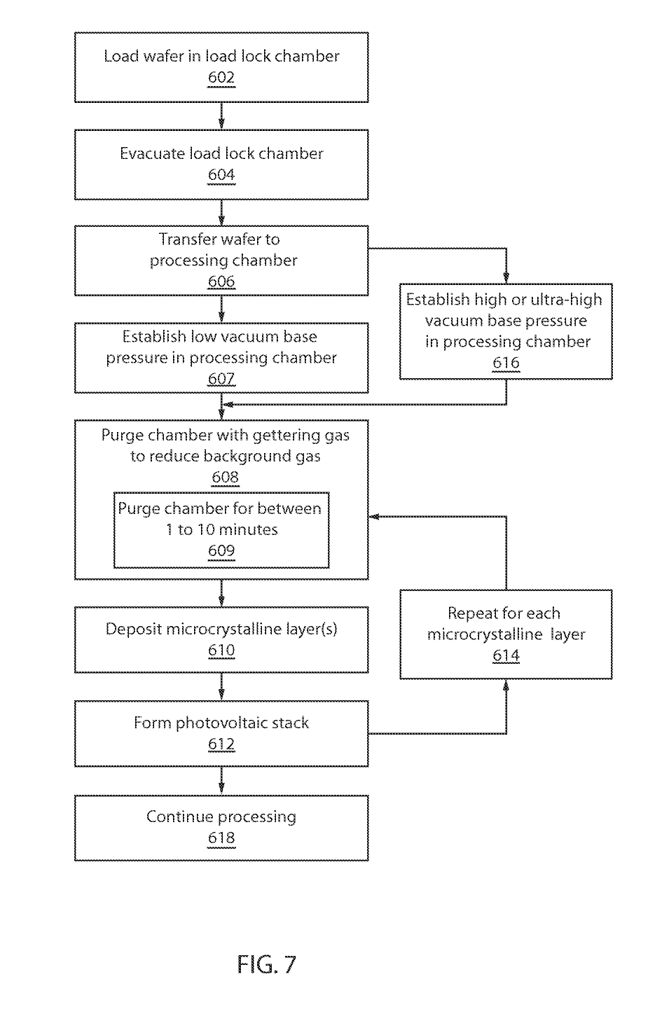

Referring to FIG. 7, a method for forming a photovoltaic device is shown in accordance with illustrative embodiments. In block 602, a wafer or substrate is loaded in a load lock chamber. PECVD and similar deposition processes are performed using a load lock chamber. In block 604, the load lock chamber is evacuated to around 10⁻¹ Torr or less.

In block 606, the wafer is then transferred to a processing PECVD chamber (which is always maintained in vacuum) and heated up to a temperature in the range of 180 degrees C. to 300 degrees C. In block 607, a base pressure in the deposition chamber is established by vacuum pumps, which may simply be a rotary mechanical pump (base pressure, in the range of 10⁻¹ to 10⁻² Torr) or established by a turbomolecular pump or other kind of vacuum pump (base pressure of 5×10⁻⁵ Torr or greater). These types of pumps are much less expensive and generally more robust than high or ultra high vacuum pumps. The vacuum base pressure of greater than about 5×10⁻⁵ Torr, and preferably greater than about 10⁻² Torr and more preferably between about 0.01 Torr and 0.1 Torr is employed (low vacuum).

In block 608, a vacuum chamber is purged with a gettering gas to remove contaminant species (background gases, nitrogen, oxygen, carbon, molecules) from the chamber prior to forming a microcrystalline layer. The gettering gas may include silane at about room temperature to about 300 degrees C. and pressure from about 1 to 20 Ton. Other temperatures and pressures may be employed. The contaminant species may include at least one of oxygen, nitrogen and carbon. Purging the vacuum chamber may occur for between 60 seconds to about 10 minutes in block 609.

In block 610, a microcrystalline material is deposited immediately after the purge by changing the gas from just silane to silane diluted in hydrogen to provide proper flux (e.g., dilution rate of silane to hydrogen from 1/50 to 1/200) for microcrystalline silicon materials and applying RF power to generate plasma. During deposition the total pressure in the chamber may be about 5-10 Torr. The microcrystalline layer may include one of a hydrogenated microcrystalline silicon, a hydrogenated microcrystalline germanium and a hydrogenated microcrystalline silicon germanium. For different microcrystal materials, different gases mixtures are employed for the plasma deposition process.

In block 612, the microcrystalline layer may be part of a photovoltaic stack of layers (pin stack or nip stack) formed over a transparent or opaque substrate. Other layers may be included as well such as electrodes, reflector layers, etc. At least one layer of the photovoltaic stack of layers includes a microcrystalline layer. The microcrystalline layer may include a doped layer or intrinsic layer. In one embodiment, the stack of layers includes one or more junctions (tandem cell), and the one or more junctions may include one or more microcrystalline layers. By providing tandem stacks, greater efficiency can be achieved over single cell devices with comparable costs. Although cost-saving microcrystalline layers described in accordance with the present principles may be for single or multi-junction devices.

In block 614, the photovoltaic stack may include a plurality of microcrystalline layers and the steps of purging and depositing are performed for each microcrystalline layer.

In block 616, in an alternate embodiment, the microcrystalline layer may be deposited after a purge using high or an ultra high vacuum base pressure established in the chamber. This embodiment employs high or ultra high vacuum in addition to the purge step.

In block 618, processing continues until the device is completed.

Having described preferred embodiments for low vacuum fabrication of microcrystalline solar cells (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method for forming a photovoltaic device, comprising:
forming a photovoltaic stack of layers on a substrate wherein at least one layer of the photovoltaic stack of layers includes a microcrystalline layer; and
forming the microcrystalline layer by:
purging a vacuum chamber with a gettering gas to remove contaminant species from the chamber prior to forming the microcrystalline layer; and
depositing the microcrystalline layer at a vacuum base pressure of greater than about 5×10⁵ Torr.

2. The method as recited in claim 1, wherein the microcrystalline layer includes one of a hydrogenated microcrystalline silicon, a hydrogenated microcrystalline germanium and a hydrogenated microcrystalline silicon germanium.

3. The method as recited in claim 1, wherein the gettering gas includes silane at a temperature of about room temperature to about 300 degrees C. and a pressure from about 1 to about 20 Torr.

4. The method as recited in claim 3, wherein the gettering gas is diluted in an inert gas.

5. The method as recited in claim 1, wherein the gettering gas includes a reactive element including sublimated titanium atoms.

6. The method as recited in claim 1, wherein the contaminant species include at least one of oxygen, nitrogen and carbon.

7. The method as recited in claim 1, wherein the microcrystalline layer includes at least an intrinsic layer of the photovoltaic stack.

8. The method as recited in claim 1, wherein the photovoltaic stack includes a plurality of microcrystalline layers and the steps of purging and depositing are performed for each microcrystalline layer.

9. The method as recited in claim 1, wherein depositing includes depositing the microcrystalline layer at a vacuum base pressure between about 0.01 Torr and about 0.1 Torr.

10. The method as recited in claim 1, wherein forming a photovoltaic stack of layers includes forming multiple junctions of a tandem cell device.

11. The method as recited in claim 1, wherein purging a vacuum chamber includes purging the vacuum chamber with silane flux for between 60 seconds to about 10 minutes.

12. A method for forming a photovoltaic device, comprising:
forming an electrode on a substrate;
forming an amorphous based silicon stack over the electrode;
forming a microcrystalline based silicon stack over the amorphous based silicon stack to form a multi-junction device, wherein at least one layer of the microcrystalline based silicon stack includes a microcrystalline layer; and
forming the microcrystalline layer by:
purging a vacuum chamber with a gettering gas to remove contaminant species from the chamber prior to form the microcrystalline layer; and
depositing the microcrystalline layer at a vacuum base pressure of greater than about 10⁻² Torr.

13. The method as recited in claim 12, wherein the microcrystalline layer includes one of a hydrogenated microcrystalline silicon, a hydrogenated microcrystalline germanium and a hydrogenated microcrystalline silicon germanium.

14. The method as recited in claim 12, wherein the gettering gas includes silane at a temperature of about room temperature to about 300 degrees C. and a pressure from about 1 to about 20 Torr.

15. The method as recited in claim 12, wherein the gettering gas is diluted in an inert gas.

16. The method as recited in claim 12 wherein the gettering gas includes a reactive element including sublimated titanium atoms.

17. The method as recited in claim 12, wherein the contaminant species include at least one of oxygen, nitrogen and carbon.

18. The method as recited in claim 12, wherein the microcrystalline layer includes at least an intrinsic layer.

19. The method as recited in claim 12, wherein the microcrystalline based silicon pin stack includes a plurality of microcrystalline layers and the steps of purging and depositing are performed for each microcrystalline layer.

20. The method as recited in claim 12, wherein depositing includes depositing the microcrystalline layer at a vacuum base pressure between about 0.01 Torr and 0.1 Torr.

21. The method as recited in claim 12, wherein purging a vacuum chamber includes purging the vacuum chamber with silane flux for between 60 seconds to about 10 minutes.

22. A method for forming a photovoltaic device, comprising:
forming a photovoltaic stack of layers on a substrate wherein at least one layer of the photovoltaic stack of layers includes a microcrystalline layer; and
forming the microcrystalline layer by:
purging a vacuum chamber with a gettering gas to remove contaminant species from the chamber prior to forming the microcrystalline layer; and
depositing the microcrystalline layer at a vacuum pressure.

23. The method as recited in claim 20, wherein the microcrystalline layer includes one of a hydrogenated microcrystalline silicon, a hydrogenated microcrystalline germanium and a hydrogenated microcrystalline silicon germanium.

24. The method as recited in claim 20, wherein the gettering gas includes silane diluted in an inert gas and including sublimated titanium atoms at a temperature of about room temperature to about 300 degrees C. and a pressure from about 1 to about 20 Torr.

25. The method as recited in claim 20, wherein the photovoltaic stack includes a plurality of microcrystalline layers and the steps of purging and depositing are performed for each microcrystalline layer.
